(19) United States
(12) Patent Application Publication
(10) Pub. No.: US 2026/0198333 A1
(43) Pub. Date: Jul. 9, 2026

(54) PRESS-PACK SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Hideaki KITAZAWA, Himeji Hyogo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/352,551

(22) Filed: Oct. 8, 2025

(30) Foreign Application Priority Data
Jan. 7, 2025 (JP) 2025-002243

(51) Int. Cl. H01L 23/00; H01L 23/495; H01L 25/065

(52) U.S. Cl. CPC H10W 70/481; H10W 70/457; H10W 90/811; H10W 72/07354; H10W 72/322; H10W 72/347; H10W 72/352; H10W 72/952; H10W 90/00; H10W 90/736

(57) ABSTRACT

A press-pack semiconductor device includes a semiconductor element including a semiconductor part and an electrode part, a first metal plate located at an upper side of the semiconductor element, a second metal plate located at a lower side of the semiconductor element, and a first metal layer located between the first metal plate and the semiconductor element. The first metal layer contacts the first metal plate and has a higher hardness than the electrode part.

### CROSS-REFERENCE TO RELATED APPLICATIONS

This application is based upon and claims the benefit of priority from Japanese Patent Application No. 2025-002243, filed on Jan. 7, 2025; the entire contents of which are incorporated herein by reference.

### FIELD

Embodiments described herein relate generally to a press-pack semiconductor device.

### BACKGROUND

A known press-pack semiconductor device with double-sided cooling realizes higher power density and high reliability under high voltages and large currents. A press-pack semiconductor device has a structure in which multiple semiconductor elements are located inside an insulating frame, sandwiched between electrode blocks above and below, and hermetically sealed. It is desirable to ensure the TFT (Thermal Fatigue Test) test durability (hereinbelow, referred to as the TFT performance) of such a press-pack semiconductor device.

### BRIEF DESCRIPTION OF THE DRAWINGS

FIG. 1 is a perspective view of a semiconductor device according to a first embodiment;

FIG. 2 is a schematic cross-sectional view of a portion of the semiconductor device;

FIG. 3 is an enlarged view of region D of FIG. 2;

FIG. 4 shows compositions of components of FIG. 3;

FIGS. 5A to 5C show structures of portions of a semiconductor element;

FIG. 6 shows compositions of components of a modification of the first embodiment;

FIG. 7 is an enlarged view of region D of a semiconductor device according to a second embodiment;

FIG. 8 shows compositions of components of the semiconductor device according to the second embodiment; and

FIG. 9 shows compositions of components of a modification of the second embodiment.

### DETAILED DESCRIPTION

A press-pack semiconductor device according to an embodiment includes a semiconductor element, a first metal plate located at an upper side of the semiconductor element, a second metal plate located at a lower side of the semiconductor element, and a first metal layer between the first metal plate and the semiconductor element. The semiconductor element includes a semiconductor part and an electrode part. The first metal layer contacts the first metal plate and has a higher hardness than the electrode part.

Embodiments of the invention will now be described with reference to the drawings. The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those already described are marked with the same reference numerals; and a detailed description is omitted as appropriate. In the description of embodiments, a direction from the center toward the outer perimeter of a semiconductor device 1 when viewed in plan also is referred to as a radial direction. In the description, a direction from a second electrode 15 toward a first electrode 10 is referred to as “up/above”, and the opposite direction is referred to as “down/below”. These directions are based on the relative positional relationship between the first electrode 10 and the second electrode 15 and are independent of the direction of gravity. In the following description, “area” means the area when viewed in plan.

### 1. First Embodiment

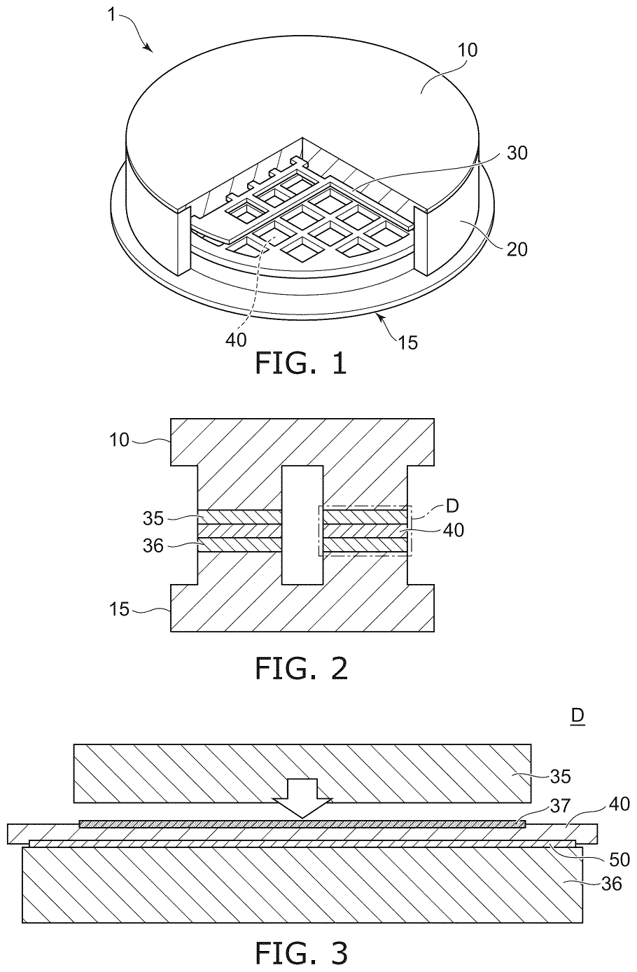

The semiconductor device 1 according to a first embodiment will now be described with reference to FIGS. 1 to 5.

As shown in FIGS. 1 and 2, the semiconductor device 1 according to the embodiment is an IEGT (Injection Enhanced Gate Transistor) as a press-pack semiconductor device, i.e., a PPI (Press-Pack IEGT). An IEGT is an IGBT (Insulated Gate Bipolar Transistor) having an electron injection enhancement effect. The semiconductor device 1 includes the first electrode 10, the second electrode 15, a housing 20, a resin frame 30, a first metal plate 35, a second metal plate 36, and a semiconductor element 40.

The first electrode 10 is located at the upper surface side of the semiconductor device 1 and functions as an emitter electrode. The second electrode 15 is located at the lower surface side of the semiconductor device 1 and functions as a collector electrode. The first electrode 10 and the second electrode 15 are, for example, circular columnar. The first electrode 10 and the second electrode 15 are formed of a metal, e.g., copper.

The housing 20 is, for example, circular tubular. The inner diameter of the housing 20 is, for example, not less than 80 mm. The thickness in the radial direction of the housing 20 is, for example, not less than 4 mm and not more than 20 mm. The housing 20 is, for example, alumina. Other than alumina, the housing 20 may include, for example, silicon nitride, zirconia, aluminum nitride, etc.

The resin frame 30 is formed of a resin and is located inside the housing 20. At least a portion of the resin frame 30 is located between the first electrode 10 and the second electrode 15. The resin frame 30 is formed in a lattice shape when viewed in plan, and holds the semiconductor elements 40 inside the rectangles of the lattice. The resin frame 30 has the functions of ensuring the insulation distance between the multiple semiconductor elements 40 and aligning the multiple semiconductor elements 40.

The first metal plate 35 is located at the upper side of the semiconductor elements 40. The second metal plate 36 is located at the lower side of the semiconductor elements 40. The first metal plate 35 and the second metal plate 36 are located between the first electrode 10 and the second electrode 15 to hold the semiconductor elements 40 from two sides. The first metal plate 35 and the second metal plate 36 favorably include a metal having a high heat resistance and breakdown voltage and are, for example, molybdenum plates.

Although the semiconductor element 40 according to the embodiment is an IEGT, the semiconductor element 40 is not particularly limited as long as the device includes electrodes above and below; and the semiconductor element 40 may be, for example, a diode such as a FRD (Fast Recovery Diode), etc. Or, the semiconductor element 40 may be a MOSFET (Metal Oxide Semiconductor Field Effect Transistor) or an IGBT. For example, an IGBT and a FRD may be provided together. The semiconductor element 40 may be a RC-IGBT (Reverse Conductive-IGBT) in which a diode and an IGBT are included in one chip. The device is not limited to silicon, and may include silicon carbide (SiC).

As shown in FIG. 3, a first metal layer 37 is located between the first metal plate 35 and the semiconductor elements 40 and contacts the upper surface of the first metal plate 35. The first metal plate 35 and the semiconductor elements 40 are pressure-bonded to each other. On the other hand, a sintered metal layer 50 is located between the second metal plate 36 and the semiconductor elements 40. The second metal plate 36 and the semiconductor elements 40 are bonded by pressure sintering. As an example, the sintered metal layer 50 includes a silver (Ag) sintered body.

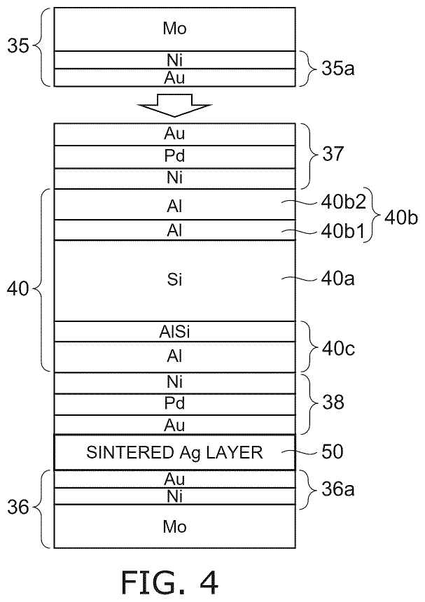

More specifically, as shown in FIG. 4, the semiconductor element 40 includes a semiconductor part 40a, an upper electrode part 40b located at the upper surface of the semiconductor part 40a, and a lower electrode part 40c located in the lower surface of the semiconductor part 40a. The upper electrode part 40b and the lower electrode part 40c also are generally referred to as simply the electrode part. Although not illustrated in FIG. 4, an emitter layer is located at the upper surface of the semiconductor part 40a; a collector layer is located at the lower surface of the semiconductor part 40a; and a gate wiring part is located at the emitter layer side. The electrode part includes, for example, aluminum (Al). As an example, the upper electrode part 40b includes a first aluminum layer 40b1 at the lower side, and a second aluminum layer 40b2 at the upper side. As examples of the thicknesses (i.e., the vertical-direction lengths) of the parts of the semiconductor element 40, the semiconductor part 40a may be 500 μm, the first aluminum layer 40b1 of the upper electrode part 40b may be 2 μm, the second aluminum layer 40b2 of the upper electrode part 40b may be 5 μm, and the aluminum layer at the lower side of the lower electrode part 40c may be 2 μm.

As an example, the first metal layer 37 includes a nickel (Ni) layer, a palladium (Pd) layer, and a gold (Au) layer in this order from below. The nickel layer that is included in the first metal layer 37 has a higher hardness than the electrode part. As examples of the thicknesses of the parts of the first metal layer 37, the nickel layer may be 1 μm, the palladium layer may be 0.1 μm, and the gold layer may be 0.1 μm.

The first metal plate 35 is a molybdenum plate; and a metal plating layer 35a is located at the surface of the first metal plate 35 facing the first metal layer 37. As an example, the metal plating layer 35a includes a nickel (Ni) layer and a gold (Au) layer in this order from above. As examples of the thicknesses of the parts of the first metal plate 35, the molybdenum layer may be 1,000 μm, the nickel layer of the metal plating layer 35a may be 1.0 μm, and the gold layer of the metal plating layer 35a may be 0.1 μm.

As an example, a second metal layer 38 includes a nickel (Ni) layer, a palladium (Pd) layer, and a gold (Au) layer in this order from above. As examples of the thicknesses of the parts of the second metal layer 38, the nickel layer may be 1.5 μm, the palladium layer may be 0.2 μm, and the gold layer may be 0.03 μm.

As an example, the second metal plate 36 is a molybdenum plate; and a metal plating layer 36a is located at the surface of the second metal plate 36 facing the second metal layer 38. As an example, the metal plating layer 36a includes a gold (Au) layer and a nickel (Ni) layer in this order from above. As examples of the thicknesses of the parts of the second metal plate 36, the molybdenum layer may be 1,000 μm, the nickel layer of the metal plating layer 36a may be 1.0 μm, and the gold layer of the metal plating layer 36a may be 0.1 μm. As the sintered metal layer 50, a sintered silver (Ag) layer is located between the second metal plate 36 and the semiconductor elements 40. As an example, the thickness of the sintered metal layer 50 may be 10 μm.

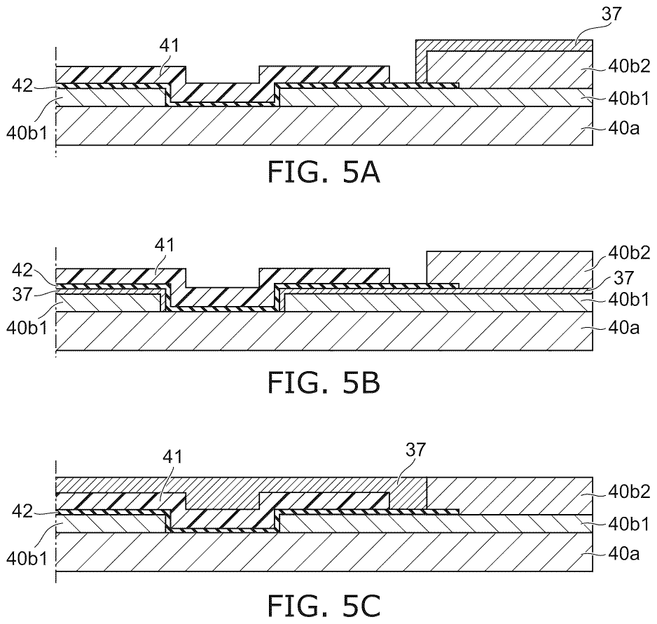

FIGS. 5A to 5C show structures of upper parts of the semiconductor elements 40. As described above, the first metal layer 37 contacts the upper surfaces of the semiconductor elements 40. As an aspect of a concrete arrangement, the first aluminum layer 40b1 and an insulating film 42 are located at the upper surface of the semiconductor part 40a as shown in FIG. 5A. An insulating layer 41 is located at the upper surface of the insulating film 42. The second aluminum layer 40b2 is located at the upper surface of the first aluminum layer 40b1. The first metal layer 37 covers the upper surface and side surface of the second aluminum layer 40b2.

Or, as another aspect of the arrangement of the first metal layer 37 as shown in FIG. 5B, the first metal layer 37 may cover the upper surface and side surface of the first aluminum layer 40b1. In such a case, the first metal layer 37 is located between the first aluminum layer 40b1 and the second aluminum layer 40b2 and between the first aluminum layer 40b1 and the insulating film 42.

Or, as another aspect of the arrangement of the first metal layer 37 as shown in FIG. 5C, the first metal layer 37 may be located at the upper surface of the insulating layer 41. In such a case, the first metal layer 37 contacts the side surface of the second aluminum layer 40b2. Thus, the technical idea of the disclosure can be concretely realized by aspects in which the first metal layer 37 contacts the upper surface of the semiconductor element 40 in various arrangements.

Thus, according to the embodiment, the semiconductor device 1 includes the first metal layer 37 that is located between the first metal plate 35 and the semiconductor elements 40, contacts the first metal plate 35, and has a higher hardness than the electrode part; therefore, horizontal sliding of the upper electrode part 40b that may occur in the semiconductor element 40 and/or wear of the upper electrode part 40b can be suppressed without performing expensive metal sintering, thereby ensuring TFT performance with a lower cost.

### Modification

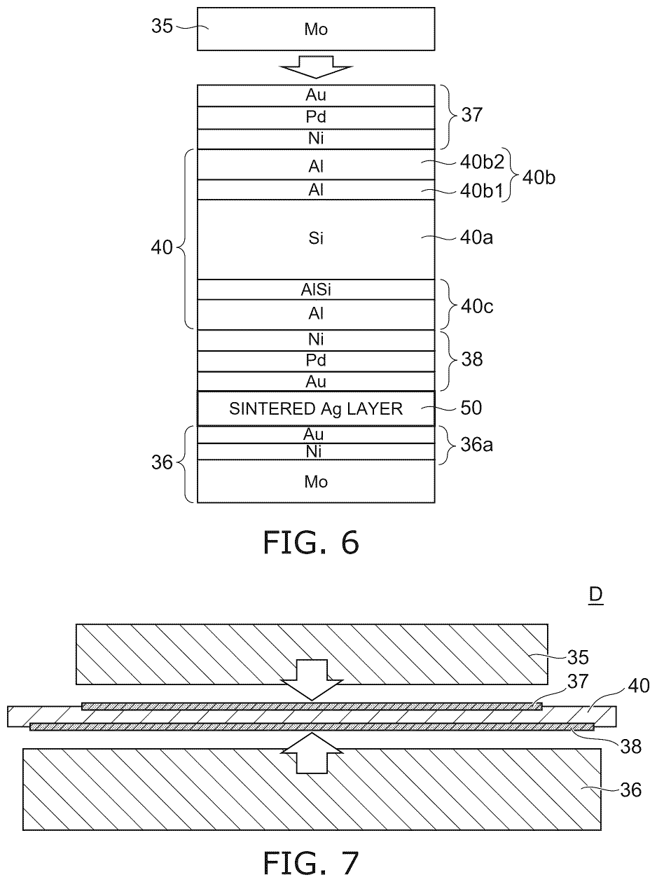

A modification of the semiconductor device 1 will now be described with reference to FIG. 6.

In the semiconductor device 1 according to the modification as shown in FIG. 6, the metal plating layer 35a is not located at the surface of the first metal plate 35 facing the first metal layer 37. Thus, even without including the metal plating layer 35a in the first metal plate 35, the technical idea of the disclosure is applicable, and effects similar to those of the embodiment above can be obtained.

### 2. Second Embodiment

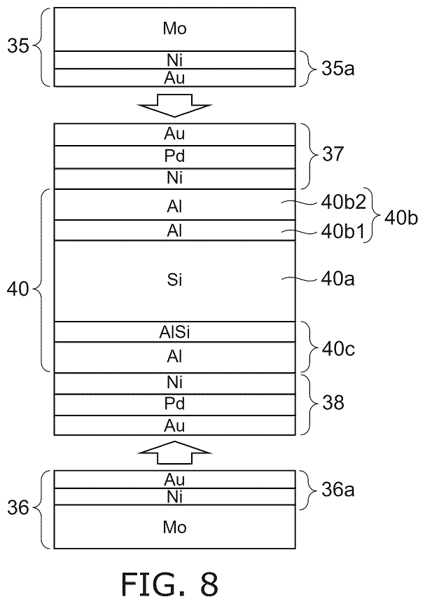

The semiconductor device 1 of a second embodiment will now be described with reference to FIGS. 7 and 8. The second embodiment differs from the first embodiment in that the second metal layer 38 is located between the second metal plate 36 and the semiconductor elements 40 without the sintered metal layer 50. The following description focuses on differences with the first embodiment.

As shown in FIG. 7, the second metal layer 38 is located between the second metal plate 36 and the semiconductor elements 40 and contacts the upper surface of the second metal plate 36. The second metal plate 36 and the semiconductor elements 40 are bonded by pressure-bonding.

More specifically, as shown in FIG. 8, the second metal layer 38 includes, for example, a nickel layer, a palladium layer, and a gold layer in this order from above. The nickel layer that is included in the second metal layer 38 has a higher melting point than the electrode part. As examples of the thicknesses of the parts of the second metal layer 38, the nickel layer may be 1.5 μm, the palladium layer may be 0.2 μm, and the gold layer may be 0.03 μm.

As an example, the second metal plate 36 is a molybdenum plate; and the metal plating layer 36a is located at the surface of the second metal plate 36 facing the second metal layer 38. As an example, the metal plating layer 36a includes a gold (Au) layer and a nickel (Ni) layer in this order from above. As examples of the thicknesses of the parts of the second metal plate 36, the molybdenum layer may be 2,000 μm, the nickel layer of the metal plating layer 36a may be 1.0 μm, and the gold layer of the metal plating layer 36a may be 0.1 μm.

Thus, according to the second embodiment, the semiconductor device 1 includes the second metal layer 38 that is located between the second metal plate 36 and the semiconductor elements 40, contacts the second metal plate 36, and has a higher melting point than the electrode part; therefore, point melting of the lower electrode part 40c that may occur in the semiconductor element 40 can be suppressed without performing expensive metal sintering; and the TFT performance can be ensured with a lower cost.

### Modification

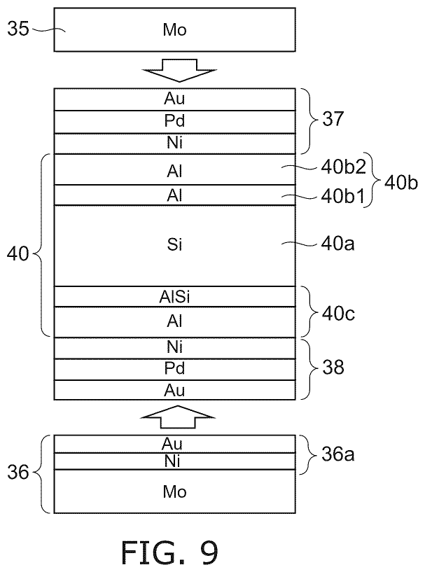

A modification of the second embodiment will now be described with reference to FIG. 9.

In the semiconductor device 1 according to the modification of the second embodiment as shown in FIG. 9, the metal plating layer 35a is not located at the surface of the first metal plate 35 facing the first metal layer 37. Thus, without including the metal plating layer 35a in the first metal plate 35, the technical idea of the disclosure is applicable; and effects similar to those of the embodiment above can be obtained.

### Other Embodiments

The technical idea of the disclosure is not limited to the examples described above. For example, according to the embodiments above, the first metal layer 37 and the second metal layer 38 have the same material composition, but the configuration is not limited to such an aspect. For example, aspects are possible in which the material composition of the first metal layer 37 is different from the material composition of the second metal layer 38.

Aspects may be different between the multiple semiconductor elements 40 included in the semiconductor device 1. For example, the first embodiment or a modification of the first embodiment is applicable to the semiconductor elements 40 located at the central part inside the housing 20; and the second embodiment or a modification of the second embodiment is applicable to the semiconductor elements 40 located at the peripheral part inside the housing 20. Also, aspects other than the first embodiment, modifications of the first embodiment, the second embodiment, and modifications of the second embodiment are applicable to several semiconductor elements 40.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A press-pack semiconductor device, comprising:
a semiconductor element including a semiconductor part and an electrode part;
a first metal plate located at an upper side of the semiconductor element;
a second metal plate located at a lower side of the semiconductor element; and
a first metal layer located between the first metal plate and the semiconductor element, the first metal layer contacting the first metal plate and having a higher hardness than the electrode part.

2. The device according to claim 1, further comprising:
a sintered metal layer located between the second metal plate and the semiconductor element.

3. The device according to claim 1, further comprising:
a second metal layer located between the second metal plate and the semiconductor element, the second metal layer contacting the second metal plate and having a higher melting point than the electrode part.

4. The device according to claim 3, wherein
a material composition of the first metal layer is different from a material composition of the second metal layer.

5. The device according to claim 1, wherein
a metal plating layer is located at a surface of the first metal plate facing the first metal layer.

6. The device according to claim 3, wherein
a metal plating layer is located at a surface of the second metal plate facing the second metal layer.

7. The device according to claim 1, wherein
the electrode part includes aluminum, and
the first metal layer includes nickel.

8. The device according to claim 3, wherein
the electrode part includes aluminum, and
the second metal layer includes nickel.

9. The device according to claim 1, wherein
the first metal plate includes molybdenum.

10. The device according to claim 1, wherein
the second metal plate includes molybdenum.

11. The device according to claim 2, wherein
the sintered metal layer includes a silver sintered body.

12. The device according to claim 1, wherein
the semiconductor element includes at least one type of element selected from the group consisting of an IEBT, a FRD, a MOSFET, and a RC-IEGT.

13. The device according to claim 1, further comprising:
a first electrode; and
a second electrode,
a plurality of the semiconductor elements being located between the first electrode and the second electrode.

14. The device according to claim 13, further comprising:
a resin frame located between the first electrode and the second electrode,
the resin frame being lattice-shaped,
the semiconductor elements being arranged inside lattice spaces of the resin frame.

15. The device according to claim 14, wherein
the first metal plate, the second metal plate, and the first metal layer are arranged inside the lattice spaces of the resin frame.

16. The device according to claim 14, further comprising:
a housing,
the plurality of semiconductor elements and the resin frame being located inside the housing.

17. The device according to claim 13, wherein
the first electrode is circular pillar-shaped, and
the second electrode is circular pillar-shaped.
